(19) United States
(12) Patent Application Publication
(10) Pub. No.: US 2025/0309786 A1
(43) Pub. Date: Oct. 2, 2025

(54) SELF-BIASING INVERTER AND CONTROL METHOD THEREOF

(71) Applicant: REALTEK SEMICONDUCTOR CORP., Hsinchu (TW)

(72) Inventors: Kuo-Wei Wu, Hsinchu (TW); Yen-Ju Lin, Hsinchu (TW)

(73) Assignee: REALTEK SEMICONDUCTOR CORP., Hsinchu (TW)

(21) Appl. No.: 19/088,438

(22) Filed: Mar. 24, 2025

(30) Foreign Application Priority Data
Mar. 27, 2024 (TW) 113111560

(51) Int. Cl. H02M 7/53846; H02H 7/122; H02M 7/00

(52) U.S. Cl. CPC H02M 7/53846; H02H 7/122; H02M 7/003

(57) ABSTRACT

A self-biasing inverter and a control method thereof related to the self-biasing inverter are provided. The self-biasing inverter includes a power terminal configured to receive a working power, an input terminal configured to receive an input signal, an output terminal configured to output an output signal related to the input signal, a first transistor electrically connected between the power terminal and the output terminal, a second transistor electrically connected between the output terminal and a ground terminal, a capacitor electrically connected between the input terminal and a node, a switch unit connected to the capacitor in parallel, and an impedance assembly electrically connected between the node and the output terminal. A control terminal of the first transistor is electrically connected to node. A control terminal of the second transistor is electrically connected to the node.

### CROSS-REFERENCE TO RELATED APPLICATION

This non-provisional application claims priority under 35 U.S.C. § 119(a) to patent application Ser. No. 11/311,1560 filed in Taiwan, R.O.C. on Mar. 27, 2024, the entire contents of which are hereby incorporated by reference.

### BACKGROUND

### Technical Field

The present disclosure relates to signal amplifier circuits, and particularly relates to a self-biasing inverter and a control method thereof.

### Related Art

Self-biasing inverter has a function of signal amplification and is widely applied to various types of circuits. However, self-biasing inverter known to the inventor has some problems. For example, in response to that a power of the self-biasing inverter known to the inventor is turned-off, the self-biasing inverter will generate a leakage current so that the self-biasing inverter still generate power consumption when the power is turned-off. In addition, in response to that the power of the self-biasing inverter known to the inventor is turned-off, the self-biasing inverter will cause an input signal or an output signal to generate noise so that other hardware elements in the circuit are affected by the noise and damaged. In other words, the power of the self-biasing inverter known to the inventor cannot be actually turned-off.

### SUMMARY

In order to address the issue(s) mentioned above, the inventors provide a self-biasing inverter. By turning-on a switch unit in response to that the power of the self-biasing inverter is turned-off, the self-biasing inverter can be prevented from being affected by AC coupling or negative feedback of a capacitor which causes overvoltage or leakage of the self-biasing inverter, and by turning-off the switch unit when the power of the self-biasing inverter is turned-off, the self-biasing inverter can be prevented from having mutual interference between the input signal and the output signal which causes circuit damage.

In some embodiments, a self-biasing inverter comprises a power terminal, an input terminal, an output terminal, a first transistor, a second transistor, a capacitor, a switch unit, and an impedance assembly. The power terminal is configured to receive a working power. The input terminal is configured to receive an input signal. The output terminal is configured to output an output signal related to the input signal. The first transistor is electrically connected between the power terminal and the output terminal, and a control terminal of the first transistor is electrically connected to a node. The second transistor is electrically connected between the output terminal and a ground terminal, and a control terminal of the second transistor is electrically connected to the node. The capacitor is electrically connected between the input terminal and the node. The switch unit is connected to the capacitor in parallel. The impedance assembly electrically is connected between the node and the output terminal. In a first mode, the power terminal receives the working power, the switch unit is turned-off, and the impedance assembly allows the node to be electrically connected to the output terminal through an impedance. In a second mode, the power terminal stops receiving the working power, the switch unit is turned-on, and the impedance assembly disconnects the node from the output terminal.

In some embodiments, the self-biasing inverter further comprises a first transmission switch and a second transmission switch. The first transmission switch is electrically connected between the power terminal and the first transistor. The second transmission switch is electrically connected between the second transistor and the ground terminal. In the first mode, the first transmission switch and the second transmission switch are turned-on. In the second mode, the first transmission switch and the second transmission switch are turned-off.

In some embodiments, the self-biasing inverter further comprises a discharging unit. One of two terminals of the discharging unit is electrically connected to the output terminal, and the other one of two terminals of the discharging unit is electrically connected to a ground.

In some embodiments, the impedance assembly is a variable impedance assembly, and the variable impedance assembly is configured to provide the impedance.

In some embodiments, the impedance assembly comprises a series circuit. The series circuit is electrically connected between the node and the output terminal, and the series circuit comprises at least one resistor and another switch unit.

In some embodiments, the at least one resistor comprises a resistor, and the resistor is electrically connected between the node and the another switch unit or between the another switch unit and the output terminal.

In some embodiments, the at least one resistor comprises two resistors, one of the two resistors is electrically connected between the node and the another switch unit, and the other one of the two resistors is electrically connected between the another switch unit and the output terminal.

In some embodiments, the inventors further provide a control method of the self-biasing inverter, comprising: in response to that a power of the self-biasing inverter is turned-on, performing the following steps: turning-off a bypass path of a capacitor and turning-on a self-biasing path of a self-biasing switch circuit; receiving an input signal through the capacitor; generating an output signal according to a change in the input signal, a working power, and a ground potential; and outputting the output signal; and in response to that the power of the self-biasing inverter is turned-off, turning-on the bypass path of the capacitor and turning-off the self-biasing path of the self-biasing switch circuit.

In some embodiments, the control method further comprises: in response to that the power of the self-biasing inverter is turned-on, turning-on a power supply path between the self-biasing switch circuit and the working power and a ground path between the self-biasing switch circuit and the ground potential; and in response to that the power of the self-biasing inverter is turned-off, turning-off the power supply path and the ground path.

In some embodiments, the control method further comprises: in response to that the power of the self-biasing inverter is turned-on, turning-off a discharging path of the self-biasing switch circuit; and in response to that the power of the self-biasing inverter is turned-off, turning-on the discharging path.

In some embodiments, the self-biasing path is a variable impedance assembly. The step of turning-on the self-biasing path of the self-biasing switch circuit comprises: adjusting an impedance value of the variable impedance assembly to turn-on the self-biasing path. The step of turning-off the self-biasing path of the self-biasing switch circuit comprises: adjusting the impedance value of the variable impedance assembly to turn-off the self-biasing path.

In some embodiments, the self-biasing path comprises at least one resistor and a switch unit.

In conclusion, according to one or some embodiments, the self-biasing inverter and the control method thereof can prevent from generating AC coupling and negative feedback in response to that the power of the self-biasing inverter is turned-off through the switch units with low cost, thereby improving a stability of the self-biasing inverter. In addition, according to one or some embodiments, the self-biasing inverter and the control method thereof can prevent from generating a leakage current in response to that the power of the self-biasing inverter is turned-off through the transmission switches with low cost, thereby reducing a power consumption of the self-biasing inverter.

### BRIEF DESCRIPTION OF DRAWINGS

The instant disclosure will become more fully understood from the detailed description given herein below for illustration only, and therefore not limitative of the instant disclosure, wherein:

FIG. 1 illustrates a schematic view of some embodiments of a self-biasing inverter;

FIG. 2 illustrates a schematic view of some other embodiments of a self-biasing inverter;

FIG. 3 illustrates a flow chart showing operations of a first implementation of the self-biasing inverter shown in FIG. 2;

FIG. 4 illustrates a flow chart showing operations of a second implementation of the self-biasing inverter shown in FIG. 2;

FIG. 5 illustrates a schematic circuit diagram for a first implementation of a first embodiment of the self-biasing inverter shown in FIG. 2;

FIG. 6 illustrates a schematic circuit diagram for a second implementation of a first embodiment of the self-biasing inverter shown in FIG. 2;

FIG. 7 illustrates a schematic circuit diagram for a first implementation of a second embodiment of the self-biasing inverter shown in FIG. 2;

FIG. 8 illustrates a schematic circuit diagram for a second implementation of a second embodiment of the self-biasing inverter shown in FIG. 2;

FIG. 9 illustrates a schematic circuit diagram for a first implementation of a third embodiment of the self-biasing inverter shown in FIG. 2;

FIG. 10 illustrates a schematic circuit diagram for a second implementation of a third embodiment of the self-biasing inverter shown in FIG. 2;

FIG. 11 illustrates a schematic circuit diagram for a first implementation of a fourth embodiment of the self-biasing inverter shown in FIG. 2; and

FIG. 12 illustrates a schematic circuit diagram for a second implementation of a fourth embodiment of the self-biasing inverter shown in FIG. 2.

### DETAILED DESCRIPTION

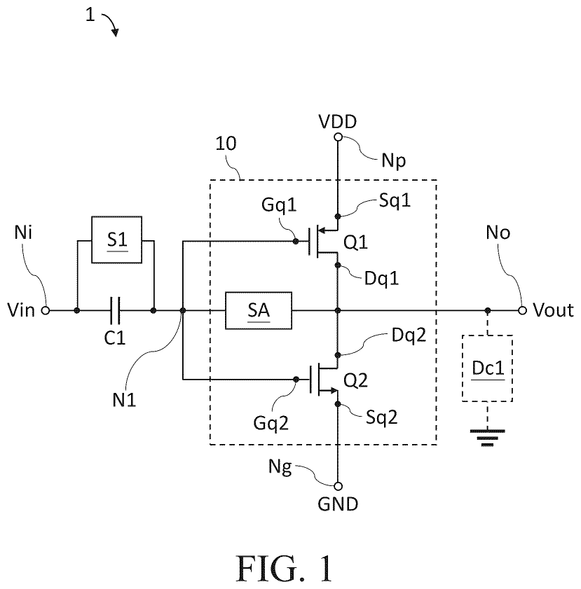

Please refer to FIG. 1 to FIG. 3. A self-biasing inverter 1 comprises a power terminal Np, an input terminal Ni, an output terminal No, a self-biasing switch circuit 10, a capacitor C1, and a bypass path. In some embodiments, the self-biasing switch circuit 10 comprises a first transistor Q1, a second transistor Q2, and a self-biasing path, and the bypass path and the self-biasing path may be a path that can be switched. In some embodiments, the bypass path may be implemented using a switch unit S1, and the self-biasing path may be implemented using an impedance assembly SA.

The power terminal Np is configured to receive a working power VDD, the input terminal Ni is configured to receive an input signal Vin, and the output terminal No is configured to output an output signal Vout related to the input signal Vin. In some embodiments, the self-biasing inverter 1 is configured to invert and amplify the input signal Vin received by the input terminal Ni into the output signal Vout when the working power VDD is provided (i.e., when the power terminal Np receives the working power VDD), and the self-biasing inverter is configured to output the output signal Vout to a next-stage circuit through the output terminal No (not shown). In other words, in some embodiments, the input signal Vin and the output signal Vout are mutually inverse, and an amplitude of the input signal Vin is less than an amplitude of the output signal Vout. In some embodiments, the input signal Vin and the output signal Vout are both analog signals. For example, in some embodiments, the input signal Vin is a sine wave (Sin) signal, and the output signal Vout is an inverse Sin signal.

Specifically, in some embodiments, the capacitor C1 is electrically connected between the input terminal Ni and a node N1, and the switch unit S1 is connected to the capacitor C1 in parallel. In other words, in some embodiment, the switch unit S1 is connected to the capacitor C1 in parallel between the input terminal Ni and the node N1 to achieve the bypass path across two terminals of the capacitor C1. In addition, the impedance assembly SA is electrically connected between the node N1 and the output terminal No to achieve the self-biasing path of the self-biasing switch circuit 10.

The first transistor Q1 is electrically connected between the power terminal Np and the output terminal No, the second transistor Q2 is electrically connected between the output terminal No and a ground terminal Ng, and a control terminal of the first transistor Q1 and a control terminal of the second transistor Q2 are electrically connected to the node N1. In some embodiments, the ground terminal Ng is configured to receive a ground potential GND. In other words, in some embodiments, the first transistor Q1 and the second transistor Q2 are controlled by the input signal Vin. In some embodiments, a voltage value of the ground potential GND is maintained at a low potential, and the ground potential GND with the low potential may be, but not limited to, for example, 0 volts, 0.1 volts, or 0.5 volts.

The first transistor Q1 has a first gate Gq1 (i.e., the control terminal of the first transistor Q1), a first drain Dq1, and a first source Sq1. The second transistor Q2 has a second gate Gq2 (i.e., the control terminal of the second transistor Q2), a second drain Dq2, and a second source Sq2. The first source Sq1 of the first transistor Q1 is electrically connected to the working power VDD, and the second source Sq2 of the second transistor Q2 is electrically connected to the ground terminal Ng. In addition, the first drain Dq1 of the first transistor Q1 and the second drain Dq2 of the second transistor Q2 are electrically connected to the output terminal No.

In some embodiments, one of two terminals of the capacitor C1 is electrically connected to the input signal Vin, and the other terminal of the capacitor C1 is electrically to the node N1. In addition, the switch unit S1 is connected to the capacitor C1 in parallel. In other words, in some embodiments, one of two terminals of the switch unit S1 is electrically connected to the input signal Vin, and the other one of two terminals of the switch unit S1 is electrically connected to the node N1. One of two terminals of the impedance assembly SA is electrically connected to the node N1, and the other one of two terminals of the impedance assembly SA is electrically connected to the output terminal No.

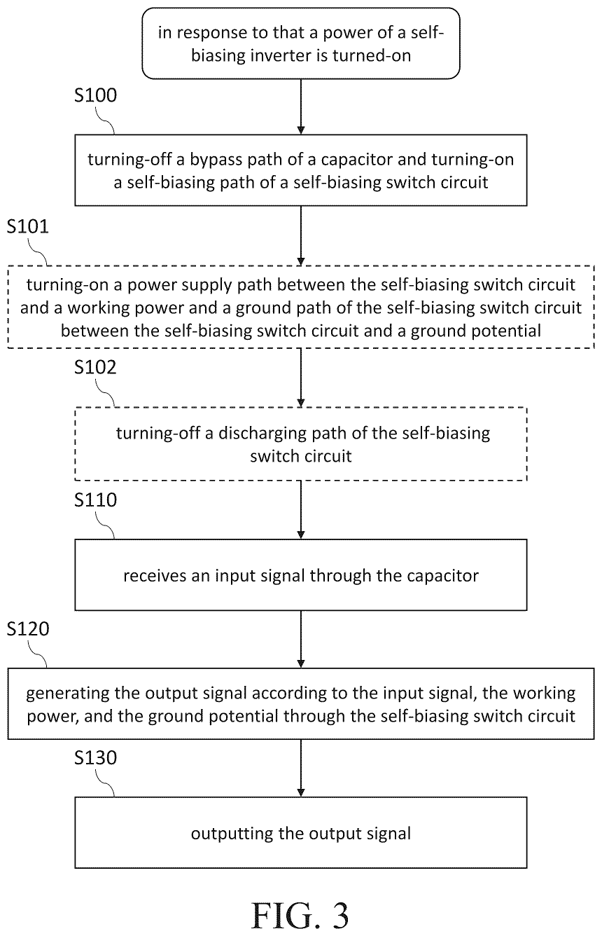

Please refer to FIG. 1 to FIG. 4. As shown in FIG. 3, in response to that a power of the self-biasing inverter 1 is turned-on (i.e., a first mode of the self-biasing inverter 1), the self-biasing inverter 1 starts to operate and receives the working power VDD with a high potential through the power terminal Np. At this moment, the self-biasing inverter 1 receives the input signal Vin through the input terminal Np, and the input signal Vin is generated by a previous-stage circuit of the self-biasing inverter 1. In some embodiments, in response to that the power of the self-biasing inverter 1 is turned-on, a voltage value of the working power VDD is pulled up to the high potential from a low potential, and the working power VDD with the high potential may be, but not limited to, for example, 3 volts, 5 volts, or 12 volts.

In response to that the power of the self-biasing inverter 1 is turned-on, the switch unit S1 is turned-off and the impedance assembly SA is turned-on. At this moment, the self-biasing inverter 1 allows the node N1 to be electrically connected to the output terminal No through the impedance assembly SA. In other words, in some embodiments, in response to that the power of the self-biasing inverter 1 is turned-on, the self-biasing inverter 1 turns-off the bypass path of the capacitor C1 and turns-on the self-biasing path of the self-biasing switch circuit 10 (the step S100).

In some embodiments, the impedance assembly SA has an impedance. In other words, in some embodiments, in response to that the power of the self-biasing inverter 1 is turned-on, the impedance assembly SA allows the node N1 to be electrically connected to the output terminal No through the impedance. Therefore, in response to that the power of the self-biasing inverter 1 is turned-on and the impedance assembly SA is turned-on, the output signal Vout is negatively fed back to the input signal Vin through the impedance assembly SA to improve a stability of the self-biasing inverter 1 and to solve problems of frequency response at the same time. Functions and influences of negative feedback and frequency response are known to a person having ordinary skills in the art and will not be described in detail here.

After the step S100, the self-biasing inverter 1 receives the input signal Vin through the capacitor C1 (the step S110). At this moment, the input signal Vin flows through the capacitor C1 to generate AC coupling, and the input signal Vin after AC coupling synchronously controls a conducting state of the first transistor Q1 and a conducting state of the second transistor Q2. In some embodiments, the conducting state of the first transistor Q1 and the conducting state of the second transistor Q2 are mutually inverse. Specifically, in some embodiments, when the first transistor Q1 is turned-on in response to the input signal Vin after AC coupling, the second transistor Q2 is synchronously turned-off in response to the input signal Vin after AC coupling. On the contrary, when the first transistor Q1 is turned-off in response to the input signal Vin after AC coupling, the second transistor Q2 is synchronously turned-on in response to the input signal Vin after AC coupling. AC coupling of the capacitor C1 is known to a person having ordinary skills in the art and will not be described in detail here.

In some embodiments, since the input signal Vin alternatively changes between a high potential (such as but not limited to 0.5 volts or 1 volts) and a low potential (such as but not limited to 0 volts or 0.1 volts), the first transistor Q1 and the second transistor Q2 are alternatively turned-on and turned-off according to the change of the input signal Vin, thereby generating the output signal Vout at the output terminal No. Take the first transistor Q1 being a P-type metal-oxide-semiconductor field-effect transistor (PMOS) and the second transistor Q2 being an N-type metal-oxide-semiconductor field-effect transistor (NMOS) for example, in response to that the input signal Vin is at the low potential, the first transistor Q1 is turned-on and the second transistor Q2 is turned-off. At this moment, the first transistor Q1 generates a pull-up current in response to turning-on (i.e., receiving) the working power VDD, so that the output terminal No is pulled up to a high potential (for example, 3 volts, 5 volts, or 12 volts) to generate the output signal Vout with the high potential. On the contrary, in response to that the input signal Vin is at the high potential, the first transistor Q1 is turned-off and the second transistor Q2 is turned-on. At this moment, the second transistor Q2 generates a pull-down current in response to turning-on the ground potential GND, so that the output terminal No is pulled down to a low potential (for example, 0 volts, 0.1 volts, or 0.5 volts) to generate the output signal Vout with the low potential.

In this embodiment, in response to that the bypass path is turned-off and the self-biasing path is turned-on, the self-biasing inverter 1 receives the input signal Vin through the capacitor C1 and generates the output signal Vout according to the input signal Vin, the working power VDD, and the ground potential GND through the self-biasing switch circuit 10 (the step S120). Last, the self-biasing inverter 1 outputs the output signal Vout to the next-stage circuit through the output terminal No (the step S130).

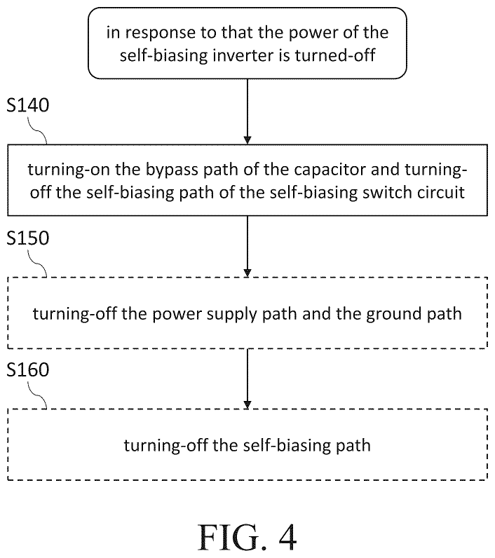

As shown in FIG. 4, in response to that the power of the self-biasing inverter 1 is turned-off (i.e., a second mode of the self-biasing inverter 1), the self-biasing inverter 1 stops operating. In some embodiments, in response to that the power of the self-biasing inverter 1 is turned-off, the voltage value of the working power VDD is pulled down to 0 volts, 0.1 volts, or 0.5 volts.

In response to that the power of the self-biasing inverter 1 is turned-off, the switch unit 1 is turned-on and the impedance assembly SA is turned-off. At this moment, the input signal Vin flows through the switch unit S1 without the capacitor C1, and a path between the node N1 (the input signal Vin) and the output terminal No (the output signal Vout) becomes an open circuit. In some embodiments, the switch unit S1 is configured to prevent the input signal Vin from flowing through the capacitor C1 to generate AC coupling in response to that the power of the self-biasing inverter 1 is turned-off. In addition, in some embodiments, the impedance assembly SA is configured to prevent from having mutual interference between the input signal Vin and the output signal Vout in response to that the power of the self-biasing inverter 1 is turned-off, thereby preventing from having mutual effect between the previous-stage circuit and the next-stage circuit that causes damage. In other words, in some embodiments, in response to that the power of the self-biasing inverter 1 is turned-off, the self-biasing inverter 1 turns-on the bypass path of the capacitor C1 and turns-off the self-biasing path of the self-biasing switch circuit 10 (the step S140).

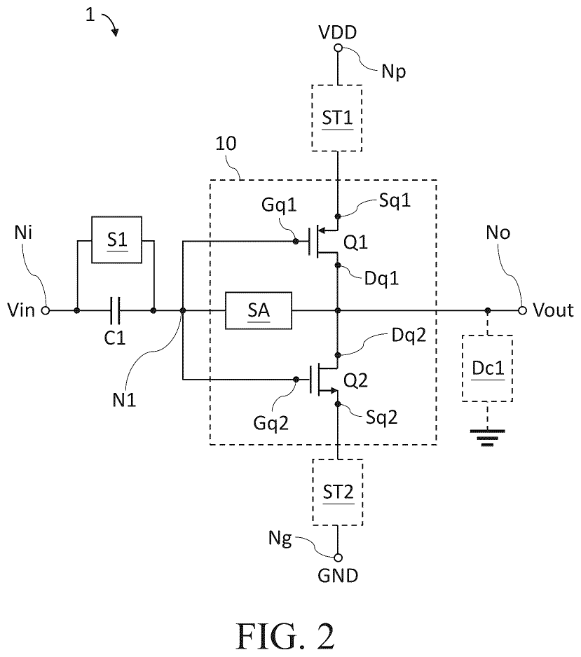

In some embodiments, the self-biasing inverter 1 further comprises a first transmission switch ST1 and a second transmission switch ST2 (as shown in FIG. 2). The first transmission switch ST1 is electrically connected between the working power VDD and the first transistor Q1, and the second transmission switch ST2 is electrically connected between the second transistor Q2 and the ground terminal Ng. In other words, in some embodiments, the self-biasing inverter 1 achieves a power supply path between the self-biasing switch circuit 10 and the working power VDD through the first transmission switch ST1, and achieves a ground path between the self-biasing switch circuit 10 and the ground potential GND through the second transmission switch ST2.

In some embodiments, in response to that the power of the self-biasing inverter 1 is turned-on, the transmission switch ST1/ST2 is turned-on so that the first transistor Q1/the second transistor Q2 is electrically connected to the working power VDD/the ground potential GND. In other words, in some embodiments, in response to that the power of the self-biasing inverter 1 is turned-on, the self-biasing inverter 1 turns-on the power supply path and the ground path of the self-biasing switch circuit 10 (the step S101). In addition, in some embodiments, in response to that the power of the self-biasing inverter 1 is turned-off, the transmission switch ST1/ST2 is turned-off to avoid the first transistor Q1/the second transistor Q2 generating a leakage current. In other words, in some embodiments, in response to that the power of the self-biasing inverter 1 is turned-off, the self-biasing inverter 1 turns-off the power supply path and the ground path of the self-biasing switch circuit 10 (the step S150).

In some embodiments, the self-biasing inverter 1 further comprises a discharging unit Dc1 (as shown in FIG. 1 and FIG. 2). One of two terminals of the discharging unit Dc1 is electrically connected to the output terminal No, and the other one of two terminals of the discharging unit Dc1 is electrically connected to the ground. In other words, in some embodiments, the self-biasing inverter 1 achieves a discharging path of the self-biasing switch circuit 10 through the discharging unit Dc1. It should be noticed that, in some embodiments, a ground potential received by the other one of two terminals of the discharging unit Dc1 and the ground potential GND received by the ground terminal Ng of the self-biasing inverter 1 are the same ground potential. In some other embodiments, the ground potential received by the other one of two terminals of the discharging unit Dc1 and the ground potential GND received by the ground terminal Ng of the self-biasing inverter 1 are different ground potentials.

In some embodiments, in response to that the power of the self-biasing inverter 1 is turned-on, the discharging unit Dc1 is turned-off. In other words, in some embodiments, in response to that the power of the self-biasing inverter 1 is turned-on, the self-biasing inverter 1 turns-off the discharging path of the self-biasing switch circuit 10 (the step S102). In addition, in some embodiments, in response to that the power of the self-biasing inverter 1 is turned-off, the discharging unit Dc1 is turned-on so that the output signal Vout is connected to the ground to be discharged. In other words, in some embodiments, in response to that the power of the self-biasing inverter 1 is turned-off, the self-biasing inverter 1 turns-on the discharging path of the self-biasing switch circuit 10 (the step S160). In some embodiments, the discharging unit Dc1 is configured to ensure that the output signal Vout is completely discharged in response to that the power of the self-biasing inverter 1 is turned-off to prevent the output signal Vout from affecting an operation of the next-stage circuit.

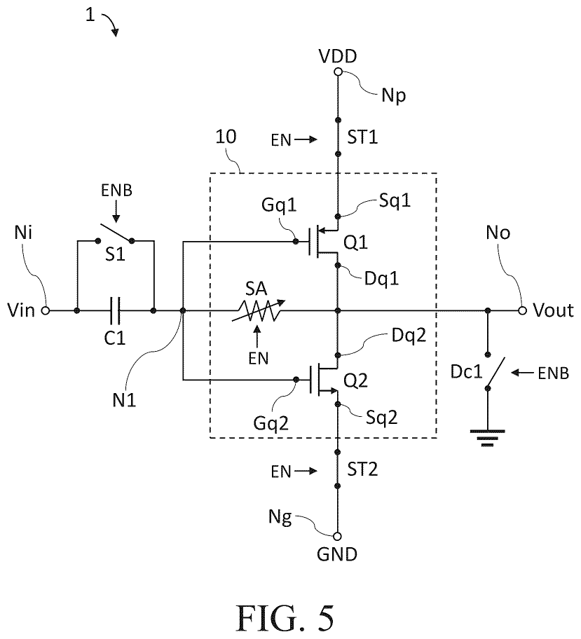

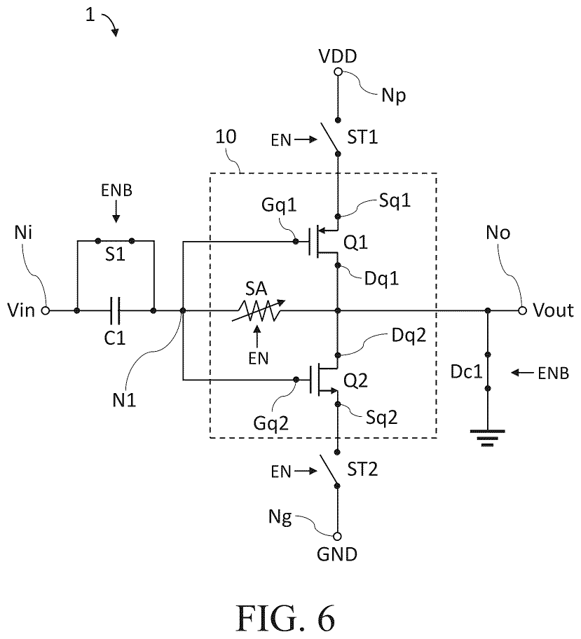

Please refer to FIG. 1 to FIG. 6. In some embodiments the impedance assembly SA may be a variable impedance assembly (as shown in FIG. 5 and FIG. 6), and the variable impedance assembly is configured to provide the impedance. In some embodiments, the variable impedance assembly may be a hardware element that has an impedance adjustment function, such as but not limited to a variable resistor or a potentiometer.

In some embodiments of the step S100, in response to that the power of the self-biasing inverter 1 is turned-on, the switch unit S1 is turned-off, and the self-biasing switch circuit 10 adjusts an impedance value of the impedance assembly SA to turn-on the impedance assembly SA (i.e., the self-biasing path). In addition, in some embodiments of the step S140, in response to that the power of the self-biasing inverter 1 is turned-off, the switch unit S1 is turned-on, and the self-biasing switch circuit 10 adjusts the impedance value of the impedance assembly SA to turn-off the impedance assembly SA (i.e., the self-biasing path). In other words, in the present embodiment, the self-biasing inverter 1 controls a connection condition between the node N1 and the output terminal No by adjusting the impedance value of the impedance assembly SA. In some embodiments, the impedance value of the impedance assembly SA is related to a current value for a signal that flows through the impedance assembly SA (for example, the output signal Vout). In other words, in some embodiments, the impedance value of the impedance assembly SA is related to the voltage value of the working power VDD. In some embodiments, in response to that the voltage value of the working power VDD is at the high potential, the impedance value of the impedance assembly SA decreases so that the impedance assembly SA is equivalent to a short circuit (i.e., the self-biasing path is turned-on); in response to that the voltage value of the working power VDD is at the low potential, the impedance value of the impedance assembly SA increases so that the impedance assembly SA is equivalent to the open circuit (i.e., the self-biasing path is turned-off).

Please refer to FIG. 1 to FIG. 4 and FIG. 7 to FIG. 12. In some embodiments, the impedance assembly SA comprises a series circuit. The series circuit is electrically connected between the node N1 and the output terminal No, and the series circuit comprises at least one resistor and another switch unit.

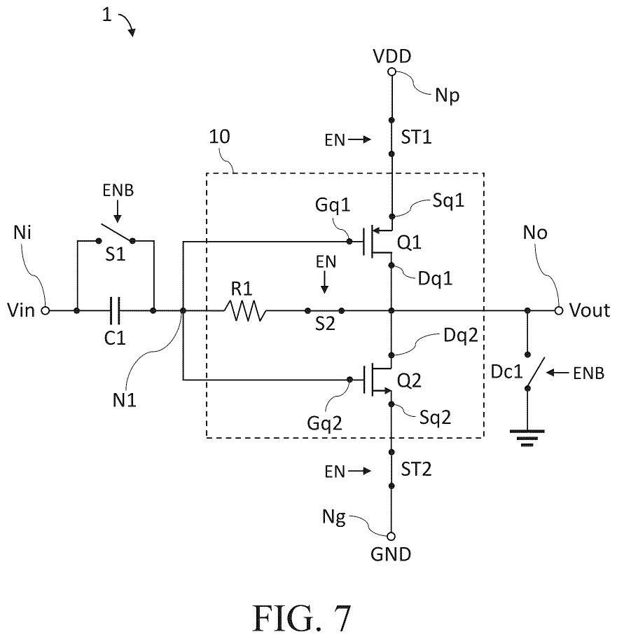

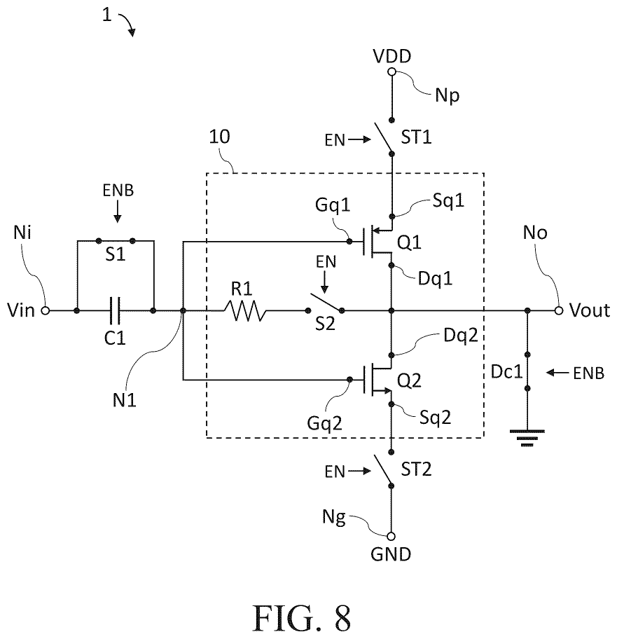

As shown in FIG. 7 and FIG. 8, in some embodiments, the impedance assembly SA comprises a resistor R1 and another switch unit S2, and the resistor R1 is electrically connected between the node N1 and the switch unit S2. In other words, in some embodiments, the switch unit S2 is electrically connected between the resistor R1 and the output terminal No. In some embodiments, the resistor R1 is configured to eliminate noise of the input signal Vin to improve a cleanliness of the input signal Vin, and the switch unit S2 is configured to control the connection condition between the node N1 and the output terminal No (i.e., the self-biasing path).

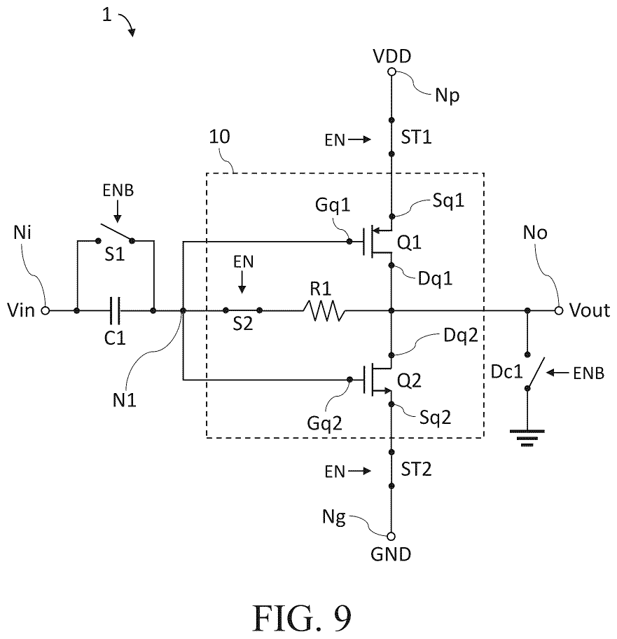

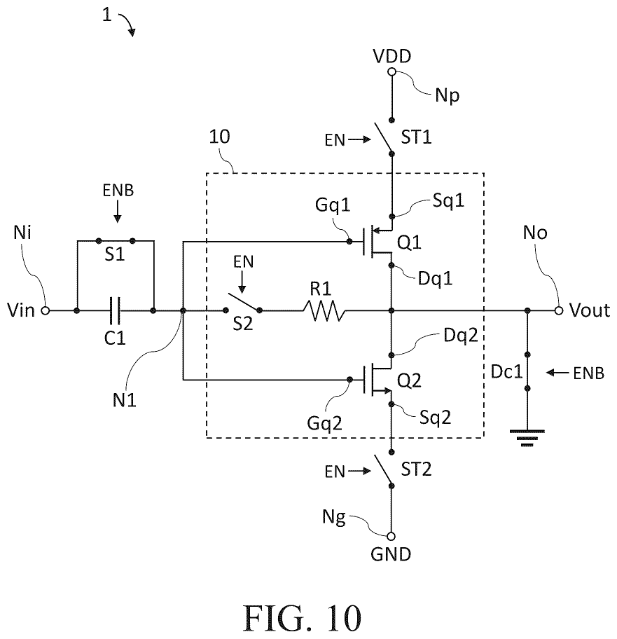

As shown in FIG. 9 and FIG. 10, in some other embodiments, the impedance assembly SA also comprises a resistor R1 and another switch unit S2, and the resistor R1 is electrically connected between the switch unit S2 and the output terminal No. In other words, in some embodiments, the switch unit S2 is electrically connected between the node N1 and the resistor R1. In some embodiments, the resistor R1 is configured to eliminate noise of the output signal Vout to improve a cleanliness of the output signal Vout, and the switch unit S2 is configured to control the connection condition between the node N1 and the output terminal No (i.e., the self-biasing path).

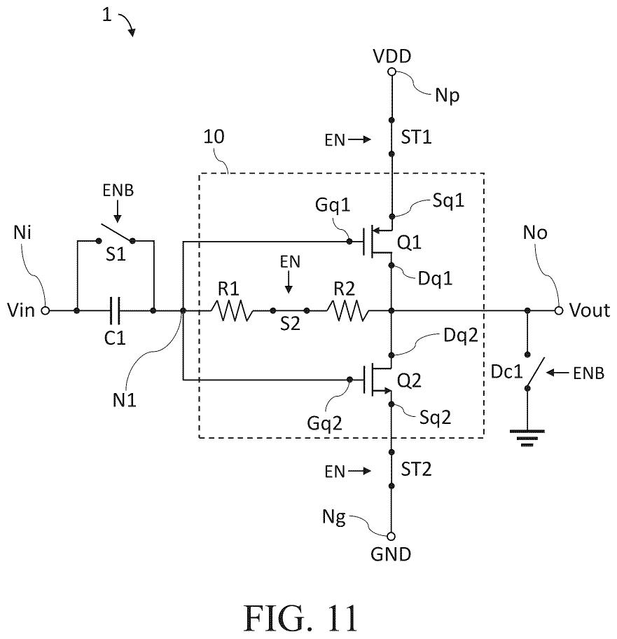

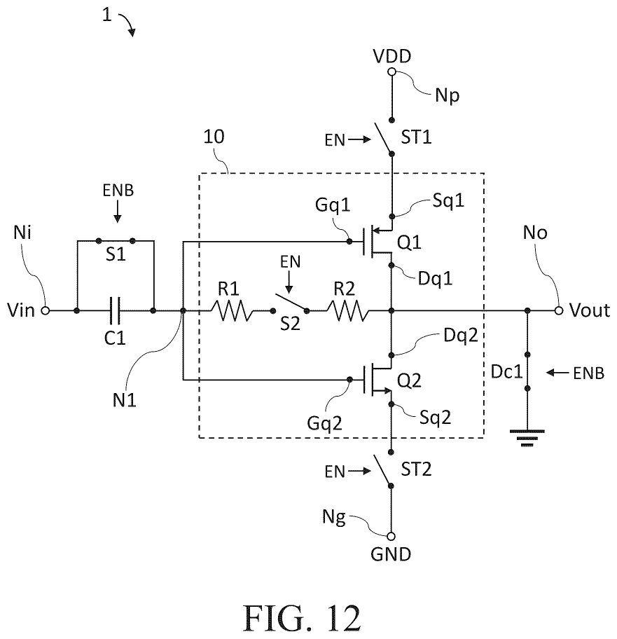

As shown in FIG. 11 and FIG. 12, in yet other embodiments, the impedance assembly SA comprises two resistors R1, R2 and another switch unit S2. The resistor R1 is electrically connected between the node N1 and the switch unit S2, and the resistor R2 is electrically connected between the switch unit S2 and the output terminal No. In other words, in these embodiments, the switch unit S2 is electrically connected between the resistor R1 and the resistor R2. In some embodiments, the resistor R1 is configured to eliminate the noise of the input signal Vin to improve the cleanliness of the input signal Vin, the resistor R2 is configured to eliminate the noise of the output signal Vout to improve the cleanliness of the output signal Vout, and the switch unit S2 is configured to control the connection condition between the node N1 and the output terminal No (i.e., the self-biasing path)

In some embodiments, the impedance value of the impedance assembly SA shown in FIG. 5 and FIG. 6 is adjusted according to a control signal EN, the first transmission switch ST1, the second transmission switch ST2, and the switch unit S2 shown in FIG. 7 to FIG. 12 are turned-on or turned-off according to the control signal EN, and the switch unit S1 and the discharging unit Dc1 shown in FIG. 5 to FIG. 12 are turned-on or turned-off according to another control signal ENB. In some embodiments, the control signals EN, ENB are mutually inverse, and the control signals EN, ENB are both related to the working power VDD. Take FIG. 7 and FIG. 8 for example, in response to that the power of the self-biasing inverter 1 is turned-on, the self-biasing inverter 1 receives the working power VDD with the high potential. At this moment, the control signal EN received by a control terminal of the first transmission switch ST1, by a control terminal of the second transmission switch ST2, and by a control terminal of the switch unit S2 is an enable potential, and the control signal ENB received by a control terminal of the switch unit S1 and by a control terminal of the discharging unit Dc1 is a disable potential. It is noted that, technologies for generating the control signals EN, ENB are known to a person having ordinary skills in the art and will not be described in detail here.

In some embodiments, in response to that the first transmission switch ST1 and the second transmission switch ST2 shown in FIG. 5 to FIG. 12 are kept turning-on, the self-biasing inverter 1 shown in FIG. 5 to FIG. 12 is equivalent to the self-biasing inverter 1 shown in FIG. 1. In other words, in the present embodiment, whether the power of the self-biasing inverter 1 is turned-on or turned-off, the power supply path and the ground path of the self-biasing switch circuit 10 are turned-on, so that the first transistor Q1 is kept being electrically connected to the working power VDD and the second transistor Q2 is kept being electrically connected to the ground potential GND.

In some embodiments, the first transistor Q1 and the second transistor Q2 each may be a transistor that has a switch function, such as but not limited to a bipolar junction transistor (BJT) or a field-effect transistor (FET). In some embodiments, the first transistor Q1 and the second transistor Q2 are transistors with opposite polarities. For example, in some embodiments, when the first transistor Q1 is a PMOS, the second transistor Q2 is an NMOS.

In some embodiments, the switch units S1, S2, the first transmission switch ST1, the second transmission switch ST2, and the discharging unit Dc1 each may be a hardware element that has a transmission function or a switch function, such as but not limited to a transmission gate, a switch diode, a BJT, or a FET.

In conclusion, according to one or some embodiments, the self-biasing inverter and the control method thereof can prevent from generating AC coupling and negative feedback in response to that the power of the self-biasing inverter is turned-off through the switch units with low cost, thereby improving a stability of the self-biasing inverter. In addition, according to one or some embodiments, the self-biasing inverter and the control method thereof can prevent from generating a leakage current in response to that the power of the self-biasing inverter is turned-off through the transmission switches with low cost, thereby reducing a power consumption of the self-biasing inverter.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A self-biasing inverter comprising:
a power terminal configured to receive a working power;
an input terminal configured to receive an input signal;
an output terminal configured to output an output signal related to the input signal;
a first transistor electrically connected between the power terminal and the output terminal, wherein a control terminal of the first transistor is electrically connected to a node;
a second transistor electrically connected between the output terminal and a ground terminal, wherein a control terminal of the second transistor is electrically connected to the node;
a capacitor electrically connected between the input terminal and the node;
a switch unit connected to the capacitor in parallel; and
an impedance assembly electrically connected between the node and the output terminal;
wherein, in a first mode, the power terminal receives the working power, the switch unit is turned-off, and the impedance assembly allows the node to be electrically connected to the output terminal through an impedance;
in a second mode, the power terminal stops receiving the working power, the switch unit is turned-on, and the impedance assembly disconnects the node from the output terminal.

2. The self-biasing inverter according to claim 1, further comprising:
a first transmission switch electrically connected between the power terminal and the first transistor; and
a second transmission switch electrically connected between the second transistor and the ground terminal;
wherein, in the first mode, the first transmission switch and the second transmission switch are turned-on;
in the second mode, the first transmission switch and the second transmission switch are turned-off.

3. The self-biasing inverter according to claim 1, further comprising:
a discharging unit, wherein one of two terminals of the discharging unit is electrically connected to the output terminal, and the other one of two terminals of the discharging unit is electrically connected to a ground.

4. The self-biasing inverter according to claim 1, wherein the impedance assembly is a variable impedance assembly, and the variable impedance assembly is configured to provide the impedance.

5. The self-biasing inverter according to claim 1, wherein the impedance assembly comprises:
a series circuit electrically connected between the node and the output terminal, wherein the series circuit comprises at least one resistor and another switch unit.

6. The self-biasing inverter according to claim 5, wherein the at least one resistor comprises a resistor, and the resistor is electrically connected between the node and the another switch unit or between the another switch unit and the output terminal.

7. The self-biasing inverter according to claim 5, wherein the at least one resistor comprises two resistors, one of the two resistors is electrically connected between the node and the another switch unit, and the other one of the two resistors is electrically connected between the another switch unit and the output terminal.

8. A control method of a self-biasing inverter comprising:
in response to that a power of the self-biasing inverter is turned-on, performing the following steps:
turning-off a bypass path of a capacitor and turning-on a self-biasing path of a self-biasing switch circuit;
receiving an input signal through the capacitor;
generating an output signal according to a change in the input signal, a working power, and a ground potential; and
outputting the output signal; and
in response to that the power of the self-biasing inverter is turned-off, turning-on the bypass path of the capacitor and turning-off the self-biasing path of the self-biasing switch circuit.

9. The control method according to claim 8, further comprising:
in response to that the power of the self-biasing inverter is turned-on, turning-on a power supply path between the self-biasing switch circuit and the working power and a ground path between the self-biasing switch circuit and the ground potential; and
in response to that the power of the self-biasing inverter is turned-off, turning-off the power supply path and the ground path.

10. The control method according to claim 8, further comprising:
in response to that the power of the self-biasing inverter is turned-on, turning-off a discharging path of the self-biasing switch circuit; and
in response to that the power of the self-biasing inverter is turned-off, turning-on the discharging path.

11. The control method according to claim 8, wherein the self-biasing path is a variable impedance assembly;
wherein, the step of turning-on the self-biasing path of the self-biasing switch circuit comprises:
adjusting an impedance value of the variable impedance assembly to turn-on the self-biasing path;
the step of turning-off the self-biasing path of the self-biasing switch circuit comprises:
adjusting the impedance value of the variable impedance assembly to turn-off the self-biasing path.

12. The control method according to claim 8, wherein the self-biasing path comprises at least one resistor and a switch unit.
